(19) United States
(12) Patent Application Publication
(10) Pub. No.: US 2015/0183992 A1
(43) Pub. Date: Jul. 2, 2015

(54) THERMOSETTING RESIN COMPOSITION AND USAGE THEREOF

(71) Applicant: Shengyi Technology Co., Ltd., Guangdong (CN)

(72) Inventors: Xianping ZENG, Guangdong (CN); Yujun XIN, Guangdong (CN)

(21) Appl. No.: 14/580,298

(22) Filed: Dec. 23, 2014

(30) Foreign Application Priority Data
Dec. 27, 2013 (CN) 201310740713.7

(51) Int. Cl. C08L 79/00; H05K 1/03; C08J 5/24; B32B 27/28; B32B 15/20; B32B 27/06; B32B 27/38; C08L 63/00; B32B 15/092

(52) U.S. Cl. CPC C08L 79/00; C08L 63/00; H05K 1/0366; C08J 5/24; B32B 15/092; B32B 15/20; B32B 27/06; B32B 27/38; B32B 27/28; H05K 2201/0355; C08J 2379/00; C08J 2463/04; C08J 2485/02; C08L 2205/03; B32B 2307/204; B32B 2307/306; B32B 2307/3065; B32B 2457/08

(57) ABSTRACT

The present invention relates to a thermosetting resin composition, wherein the resin composition comprises: (A) an epoxy resin with main chain containing naphthol structure; (B) a cyanate ester compound or/and an isocyanate ester prepolymer; (C) a poly phosphonate ester or/and phosphonate-carbonate copolymer. The thermosetting resin provided by the present invention has low dielectric constant and dielectric loss angular tangent value. The prepreg and copper-clad laminate made from the thermosetting resin composition above has excellent dielectrical properties, wet-heat resistance, flame resistance of UL94 V-0 grade and good technical processing performance.

### TECHNICAL FIELD

The present invention relates to a thermosetting resin composition, particularly to a halogen-free thermosetting resin composition, and prepreg, laminate and high-frequency circuit board made from them.

### BACKGROUND ART

As the information processing of electronic products becomes more and more high-speed and multifunctional, the amount of transmitted information continuously increases, the application frequency is required increase constantly, and moreover, the communication devices are continuously miniaturized, thereby the requirement for the electronic devices which are more miniaturized, lightweight and capable of high-speed information transmission becomes more and more urgent. At present, the operating frequency of the conventional communication device is generally more than 500 MHz, 1-10 GHz for most of them; with the demand on transmission of large information in a short time, the operating frequency also increases continuously. But signal integrity problems arise with the increasing frequency. As a basic material of signal transmission, the dielectric property of the copper clad laminates is one of the major factors influencing the signal integrity. In general, the smaller the dielectric constant of the substrate material is, the faster the transmission rate will be, the smaller the dielectric loss tangent value will be, and the better the signal integrity will be. For substrates, how to reduce the dielectric constant and dielectric loss tangent becomes a hot issue in technical research in recent years.

In addition, in order to meet the requirements for PCB processing performance and terminal electronic products performance, the copper-clad substrate material must has good dielectric properties, heat resistance and mechanical properties, and also has good processing characteristics, high peel strength, low water absorption, excellent wet-heat resistance and UL94 V-0 flame resistance levels.

As we all know, there are a variety of materials with small dielectric constant and dielectric loss tangent characteristic, such as polyolefins, fluorine resins, polystyrene, polyphenylene ether, modified polyphenylene ether, bismaleimide-triazine resin and polyvinyl benzene resins. Although the resins above have good dielectric properties, they all have defects such as processing difficulty and poor heat resistance, and therefore unable to meet the requirements of the copper-clad substrate.

### SUMMARY OF THE INVENTION

One object of the present invention is to provide a thermosetting resin composition, which can provide excellent dielectric properties, wet-heat resistance and mechanical properties which is required for the copper clad laminate. Meanwhile, it also have good processing characteristics, high peel strength, low water absorption, high Tg, excellent wet-heat resistance performance and UL 94 V-0 level of halogen-free flame resistance.

To achieve the object above, the present invention employs the following technical solutions

A thermosetting resin composition, wherein the resin composition comprises:

(A) epoxy resin with main chain containing naphthol structure;
(B) cyanate ester compound and/or cyanate ester prepolymer;
(C) polyphosphonate ester and/or phosphonate-carbonate copolymer.

The present invention adopted polyphosphonate ester and/or phosphonate-carbonate copolymer as flame retardant, having the advantages of high molecular weight, excellent heat resistance and low plasticity. The present invention adopted the epoxy resin with main chain containing naphthol structure, thus having low water absorption rate, and more excellent heat resistance and dielectrical property.

Preferably, the polyphosphonate ester has the following structural formula:

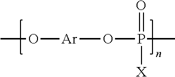

wherein Ar is an aryl, —O—Ar—O— is any one selected from the group of resorcinol active group, hydroquinone active group, bisphenol A active group, bisphenol F active group, 4,4′-bisphenol, phenolphthalein active group, 4,4′-thiodiphenol active group, 4,4′-sulfonyl diphenol active group and 3,3,5-trimethylcyclohexyl diphenol active group; X is substituted or unsubstituted C1-C20 straight-chain alkyl, substituted or unsubstituted C1-C20 branched-chain alkyl, substituted or unsubstituted C2-C20 straight-chain alkenyl, substituted or unsubstituted C2-C20 branched-chain alkenyl, substituted or unsubstituted C2-C20 straight-chain alkylene, substituted or unsubstituted C2-C20 branched-chain alkylene, substituted or unsubstituted C5-C20 cycloalkyl, or substituted or unsubstituted C6-C20 ranched-chain aryl; n is any integer from 1 to 75, such as 2, 5, 8, 10, 15, 20, 25, 30, 35, 40, 45, 50, 55, 60, 65, 70 or 72.

Preferably, the structural formula of the phosphonate-carbonate copolymer is as follows:

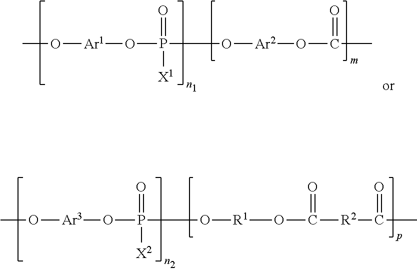

wherein, Ar¹, Ar² and Ar³ are each independently selected from aryl and the —O-Ar3-O— is any one selected from the group of resorcinol active group, hydroquinone active group, bisphenol A active group, bisphenol F active group, 4,4′-bisphenol, phenolphthalein activity group, 4,4′-thiodiphenol active groups, 4,4′-sulfonyl diphenol active group and 3,3,5-trimethylcyclohexyl diphenol active group; X¹ and X² are each independently substituted or unsubstituted C1-C20 straight-chain alkyl, substituted or unsubstituted C1-C20 branched-chain alkyl, substituted or unsubstituted C2-C20 straight-chain alkenyl, substituted or unsubstituted C2-C20 branched-chain alkenyl, substituted or unsubstituted C2-C20 straight-chain alkylene, substituted or unsubstituted C2-C20 branched-chain alkylene, substituted or unsubstituted C5-C20 cycloalkyl, or substituted or unsubstituted C6-C20 branched-chain aryl; m is any integer from 1 to 100, n₁ and n₂ are each independently any integer from 1 to 75, and p is any integer from 2 to 50; R¹, R² are each independently selected from the group of substituted or unsubstituted aliphatic or aromatic hydrocarbon group, preferably selected from unsubstituted aliphatic or aromatic hydrocarbon group.

“Aryl” refers to any functional group or substituent derived from an aromatic ring. Illustrative examples of aromatic ring include methylbenzene, Ethylbenzene, n-propylbenzene, isopropylbenzene, styrene, phenol, acetophenone, anisole, ethoxybenzene, benzyl alcohol, benzaldehyde, benzoyl chloride, benzoic acid, cyanobenzene, nitrobenzene, nitrosyl benzene, aniline, fluorobenzene, chlorobenzene, bromobenzene, iodobenzene, benzenesulfonic acid, diphenyl ketone, benzil, phenylacetic acid, mandelic acid, cinnamic acid, acetanilide, phenethylamine, azobenzene, benzene diazonium chloride, benzoyl peroxide, benzyl chloride, benzenesulfonyl chloride, diphenylmethane, triphenylmethane, trityl alcohol, trityl chloride, tetraphenyl methane, xylene (o-toluene, m-xylene, p-xylene), dihydroxyhenzene (o-dihydroxybenzene, resorcinol, hydroquinone), phthalic acid (phthalic acid, m phthalic acid, terephthalic acid), phenylenediamine (o-phenylenediamine, m-phenylenediamine, p-phenylenediamine), toluidine (o-toluidine, m-toluidine, p-toluidine), benzene-m-disulfonic acid, toluene-p-sulfonic acid, p-aminobenzoic acid, salicylic acid, acetylsalicylic acid, acetaminophen, phenacetin, m-chloroperoxybenzoic acid, mesitylene, unsym-trimethyl benzene, durene, gallic acid, pyrogallol, picric acid, trinitrotoluene, tribromo phenol, pentachlorophenol, mellitic acid, biphenyl, terphenyl, naphthalene, anthracene, phenanthrene, benzoquinone (o-benzoquinone, p-benzoquinone), and the aryl can be any functional group or substituent derived from the anaromatic ring mentioned above.

In the present invention, the structural formula of component (A) the epoxy resin with main chain containing naphthol structure is as follows:

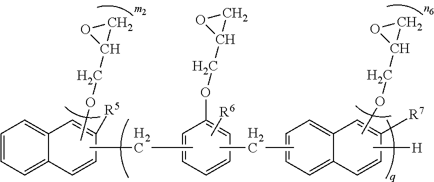

wherein, m₂, n₆ are each independently selected from the group of 0, 1 or 2, q is any integer from 1 to 10, such as 2, 3, 4, 5, 6, 7, 8 or 9, and m₂+n₆+q≧2, R⁵, R⁶, R⁷ are each independently any one selected from the group of H, substituted or unsubstituted C1-C5 straight-chain alkyl of and substituted or unsubstituted C1-C5 branched-chain alkyl or alkoxy.

Preferably, the polyphosphonate ester or/and phosphate-carbonate copolymer is any one or mixture of at least two selected from the group of

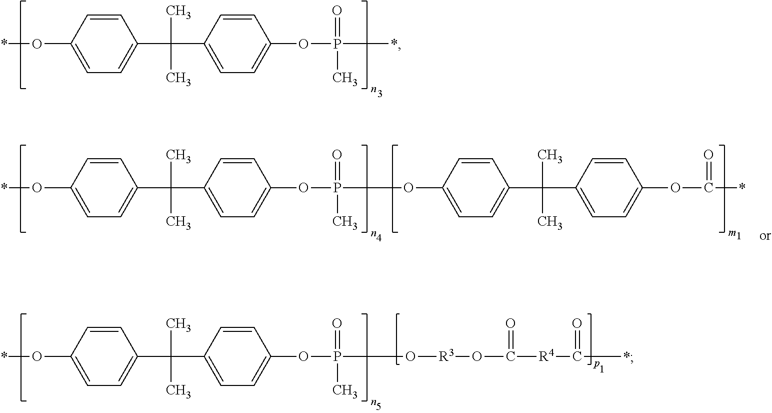

Wherein, R³ and R⁴ are each independently selected from substituted or unsubstituted aliphatic or aromatic hydrocarbon groups, preferably selected from unsubstituted aliphatic or aromatic hydrocarbon groups; m₁ is any integer from 1 to 100; n₃, n₄ and n₅ are each independently any integer from 1 to 75; p₁ is any integer from 2 to 50.

Preferably, m and m₁ are each independently any integer between 5 and 100, and preferably m and m₁ are each independently any integer between 10 and 100.

Preferably, n₁, n₂, n₃, n₄ and n₅ are each independently any integer between 5 and 75, and preferably n₁, n₂, n₃, n₄ and n₅ are each independently any integer between 10 and 75.

Preferably, p and p₁ are each independently any integer between 5 and 50, and preferably p and p₁ are each independently any integer between 10 and 50.

m and m₁ are each independently such as 2, 5, 10, 15, 20, 25, 30, 35, 40, 45, 50, 55, 60, 65, 70, 75, 80, 85, 90 or 95.

n₁, n₂, n₃, n₄ and n₅ are each independently such as 2, 5, 8, 10, 15, 20, 25, 30, 35, 40, 45, 50, 55, 60, 65, 70 or 72.

p and p₁ are each independently such as 3, 5, 10, 14, 18, 22, 26, 30, 34, 38, 42, 45 or 48.

The weight-average molecular weight of the polyphosphonate ester and/or phosphonate-carbonate copolymer is 1000-60000, preferably 5000-50000 and more preferably 10000-45000. When the weight-average molecular weight is below 1000, after addition to the cured resin, the heat resistance of the cured product will be reduced, for example, the glass transition temperature will decrease; however when the weight-average molecular weight is more than 60000, the polyphosphonate ester and/or phosphonate-carbonate copolymer has very poor solubility in organic solvent, thus good and uniform resin glue cannot be obtained and the technical requirements of copper clad laminate cannot be met.

The cyanate ester refers to the resin which contains two or more than two hydroxyl groups (—OCN) in its molecular structure.

Preferably, the cyanate ester compound of the present invention has the following structural formula:

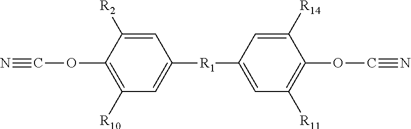

wherein, R₁ is selected from

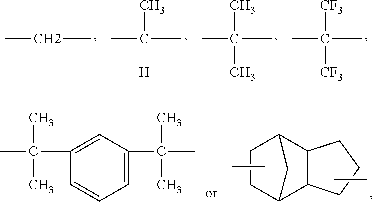

R₂, R₃, R₁₀ and R₁₁ are each independently any one selected from the group of hydrogen atom, substituted or unsubstituted C1-C4 straight-chain alkyl and substituted or unsubstituted C1-C4 branched-chain alkyl.

Preferably, the cyanate prepolymer of the present invention has the following structural formula:

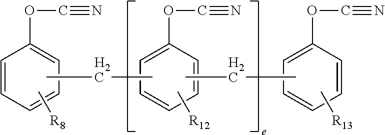

wherein, R₈, R₁₂ and R₁₃ are each independently any one selected from the group of hydrogen atom, substituted or unsubstituted C1-C4 straight-chain alkyl and substituted or unsubstituted C1-C4 branched-chain alkyl; e is any integer from 1 to 7.

Preferably, the component (B) is one or mixture of at least two selected from 2,2-bis(4-cyanatophenyl)propane, bis(4-cyanatophenyl)ethane, bis(3,5-dimethyl-4-cyanatophenyl)methane, 2,2-bis(4-cyanatophenyl)-1,1,1,3,3,3-hexafluoropropane, α,α′-bis(4-cyanatophenyl)-m-diisopropylbenzene, cyclopentadiene-type cyanate, Phenol Novolac Cyanate Ester, Cresol novolac cyanate ester, 2,2-bis(4-cyanatophenyl)propane prepolymer, bis(4-cyanatophenyl)ethane prepolymer, bis(3,5-dimethy-4-cyanatophenyl)methane prepolymer, 2,2-bis(4-cyanatophenyl)-1,1,1,3,3,3-hexafluoropropane prepolymer, α,α′-bis(4-cyanatophenyl)-m-diisopropylbenzene prepolymer, cyclopentadiene-type cyanate prepolymer, phenol novolac cyanate ester prepolymer and cresol novolac cyanate ester prepolymer; preferably any one or mixture of at least two selected from a group consisting of bis(4-cyanato phenyl) propane, α,α′-bis(4-cyanatophenyl)-m-diisopropylbenzene, bis(3,5-dimethyl-4-cyanatophenyl)methane, 2,2-bis(4-cyanatophenyl)propane prepolymer, α,α′-bis(4-cyanatophenyl)-m-diisopropylbenzene prepolymer or bis(3,5-dimethyl-4-cyanato phenyl) methane prepolymer.

Illustrative (B) cyanate ester compounds or/and isocyanate ester prepolymer is such as the mixture of 2-bis-(4-cyanatophenyl)propane and bis(4-cyanatophenyl)ethane, the mixture of bis-(3,5-dimethyl-4-cyanatophenyl) methane and 2,2-bis(4-cyanatophenyl)-1,1,1,3,3,3-hexafluoropropane, the mixture of α,α′-bis(4-cyanatophenyl)-m-diisopropylbenzene and cyclopentadiene-type cyanate, the mixture of phenol novolac cyanate ester and cresol novolac cyanate ester, the mixture of 2,2-bis(4-cyanatophenyl)propane prepolymer, bis(4-cyanatophenyl)ethane prepolymer and bis(3,5-dimethyl-4-cyanatophenyl)methane prepolymer, the mixture of 2,2-bis(4-cyanatophenyl)-1,1,1,3,3,3-hexafluoropropane prepolymer, α,α′-bis(4-cyanatophenyl)-m-diisopropylbenzene prepolymer, and the mixture of cyclopentadiene-type cyanate ester prepolymer, phenol novolac-type cyanate ester prepolymer and cresol novolac-type cyanate ester prepolymer.

Preferably, (A) the epoxy resin with main chain containing naphthol structure is any one or mixture of at least two selected from the epoxy resin having the following structure:

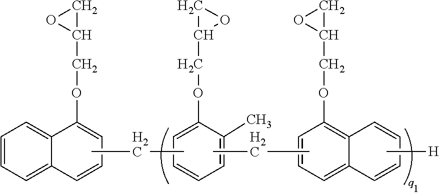

q₁ is any integer from 1 to 10, such as 2, 3, 4, 5, 6, 7, 8 or 9;
or

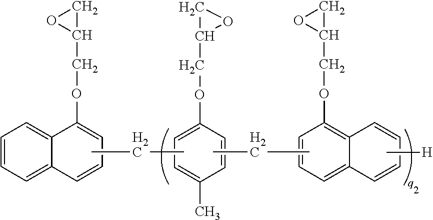

q₂ is any integer from 1 to 10, such as 2, 3, 4, 5, 6, 7, 8 or 9;
or

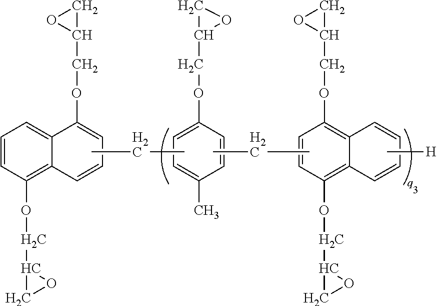

q₃ is any integer from 1 to 10, such as 2, 3, 4, 5, 6, 7, 8 or 9;
or

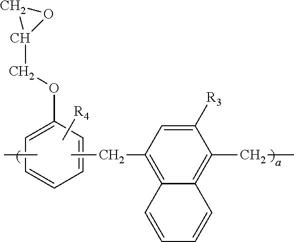

a is any integer from 2 to 10, such as 3, 4, 5, 6, 7, 8 or 9; R₃, R₄ is independently any one selected from the group of hydrogen atoms, substituted or unsubstituted C1-C5 straight-chain alkyl and substituted or unsubstituted C1-C5 branched-chain alkyl or alkoxy.

A thermosetting resin composition, wherein the resin composition comprises (A) epoxy resin with main chain containing naphthol structure and (B) cyanate ester compounds or/and isocyanate ester prepolymer: 70-95 weight parts, such as 72 weight parts, 74 weight parts, 76 weight parts, 78 weight parts, 80 weight parts, 84 weight parts, 82 weight parts, 86 weight parts, 88 weight parts, 90 weight parts, 92 weight parts or 94 weight parts, (C) polyphosphonate ester or/and phosphonate-carbonate copolymers: 5-30 weight parts, such as 7 weight parts, 9 weight parts, 11 weight parts, 13 weight parts, 15 weight parts, 17 weight parts, 19 weight parts, 21 weight parts, 23 weight parts, 25 weight parts, 27 weight parts or 29 weight parts.

In the present invention, based on the calculation of usage amount of (A) epoxy resin with main chain containing naphthol structure as 100 weight parts, the addition amount of cyanate ester compounds or/and isocyanate ester prepolymer is 20-100 weight parts, such as 25 weight parts, 30 weight parts, 35 weight parts, 40 weight parts, 45 weight parts, 50 weight parts, 55 weight parts, 60 weight parts, 65 weight parts, 70 weight parts, 75 weight parts, 80 weight parts, 85 weight parts, 90 weight parts or 95 weight parts.

Those skilled in the art can obtain the thermosetting resin composition of the present invention by selecting suitable components such as cured agents, promotors etc., to coordinate with components (A), (B) and (C) according to the formulation of the thermosetting resin composition disclosed in the prior art.

In the present invention, further the thermosetting resin composition may also comprises (D) active ester curing agent. The active ester curing agent is prepared from the reaction of phenolic compounds with structural formula of

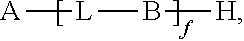

aromatic dicarboxylic acid or acid halides and monohydroxyl compounds, wherein, A, B is independently selected from the phenolic groups, L is alicyclic group and f is any integer from 1 to 5. The active ester curing agent mainly has the effect of curing epoxy resin. After it cured epoxy resin, there is no generation of secondary hydroxyl, therefore there exists no hydroxyl polar groups in the cured product, thereby it has good dielectrical properties, low water absorption rate and good wet-heat resistance.

Preferably, phenolic compounds with a structural formula of

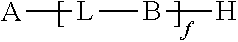

is any one or mixture of at least two selected from the phenolic compound with the following structure:

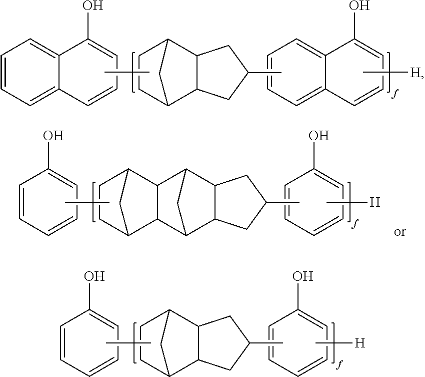

wherein, f is any integer from 1 to 5.

The aromatic dicarboxylic acid is any one or mixture of at least two selected from the aromatic dicarboxylic with the following structure:

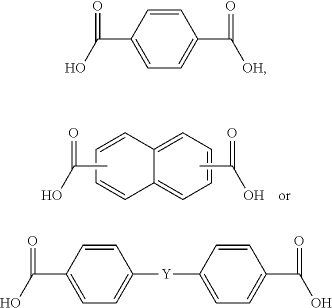

wherein, Y is selected from substituted or unsubstituted C1-C5 straight-chain alkylene or substituted or unsubstituted C1-C5 branched-chain alkylene.

Based on the usage amount of the aromatic dicarboxylic acid or acid halide of 1 mol, the usage amount of the phenolic compounds with a structural formula of

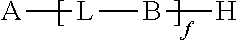

is 0.05-0.75 mol, such as, 0.1 mol, 0.15 mol, 0.2 mol, 0.25 mol, 0.3 mol, 0.35 mol, 0.4 mol, 0.45 mol, 0.5 mol, 0.55 mol, 0.6 mol, 0.65 mol or 0.7 mol, and the usage amount of monohydroxyl compounds is 0.25-0.95 mol, 0.3 mol, 0.35 mol, such as 0.4 mol, 0.45 mol, 0.5 mol, 0.55 mol, 0.6 mol, 0.65 mol, 0.7 mol, 0.75 mol, 0.8 mol, 0.85 mol or 0.9 mol.

Furthermore, the active ester curing agent has the following structural formula:

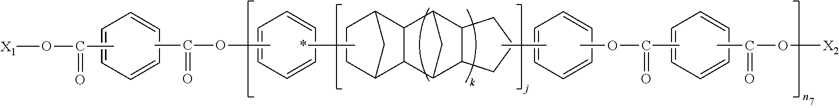

wherein, X₁ and X₂ are independently selected from benzene or naphthalene ring, j is 0 or 1, K is 0 or 1, n₇ represents the average repeat unit of 0.25-2.5.

Usage amount of the active ester curing agent is based on the ratio of epoxy equivalent and active ester equivalent and the equivalence ratio is 0.25-1.0, such as 0.3, 0.35, 0.4, 0.45, 0.5, 0.55, 0.6, 0.65, 0.7, 0.75, 0.8, 0.85, 0.9 or 0.95, preferably equivalent ratio is 0.3-0.95, most preferably equivalence ratio is 0.4-0.7. Addition of active ester mainly aims to cure epoxy resin with cyanate ester, thereby further reduce the Dk/Df.

A thermosetting resin composition, wherein the resin composition comprises (A) epoxy resin with main chain containing naphthol structure and (B) cyanate ester compounds or/and isocyanate ester prepolymer: 70-95 weight parts, (C) polyphosphonate ester or/and phosphonate-carbonate copolymers: 5-30 weight parts; based on the calculation of usage amount of (A) epoxy resin with main chain containing naphthol structure as 100 weight parts, the addition amount of (B) cyanate ester compounds or/and isocyanate ester prepolymer is 20-100 weight parts.

A thermosetting resin composition, wherein the resin composition comprises (A) epoxy resin with main chain containing naphthol structure and (B) cyanate ester compounds or/and isocyanate ester prepolymer: 70-95 weight parts, (C) polyphosphonate ester or/and phosphonate-carbonate copolymers: 5-30 weight parts; based on the calculation of usage amount of (A) epoxy resin with main chain containing naphthol structure as 100 weight parts, the addition amount of (B) cyanate ester compounds or/and isocyanate ester prepolymer is 20-100 weight parts; usage amount of the active ester curing agent is based on the ratio of epoxy equivalent and active ester equivalent and the equivalence ratio is 0.25-1.0, preferably equivalent ratio is 0.3-0.95, most preferably equivalence ratio is 0.4-0.7.

If necessary, the thermosetting resin composition of the present invention can further comprises component (E) filler. There is no special limitation for the filler added according to need. The filler is selected from organic and/or inorganic filler, preferably the inorganic filler, further preferably the surface-treated inorganic filler, and most preferably, the surface-treated silicon dioxide.

The surface treatment agent for surface treatment is one or mixture of at least two selected from the group of silane coupling agents, organosilicone oligomer, or titanate coupling agent. The silane coupling agents is one or mixture of at least two selected from the group of vinyl tri-methoxysilane, vinyltriethoxysilane, glycerol propyl trimethoxy silane, 2-(3,4-epoxy cyclohexyl)ethyltrimethoxy silaneand, 3-glycidoxy propyl triethoxysilane, 3-glycidoxy methyl dimethoxy silane, p-isobutylene trimethoxy silane, 3-propyl methacrylate triethoxy silane, 3-propyl methacrylate Methyldimethoxy silane, 3-propyl methacrylate Methyl dioxolmeth silane, 3-allyl trimethoxysilane, N-2-(aminoethyl)-3-aminopropyl triethoxy silane, 3-aminopropyl triethoxy silane, 3-triethoxysilyl monosilane-N-(I,3-dimethyl-butyl) propylamine, N-phenyl-3-ammonia propyl trimethoxy silane or 3-isocyanate propyl triethoxy silane; The usage amount of the silane coupling agents is not specified. Based on the calculation of inorganic filler as 100 weight parts, the usage amount of surface treatment agent is 0.1-5.0 weight parts, preferably 0.5-3.0 weight parts, more preferably 0.75-2.0 weight parts.

The inorganic filler is any one or mixture of at least two selected from the group of nonmetal oxide, metal nitride, non metal nitride, Inorganic hydrate, inorganic salt, metal hydrate or inorganic phosphorus; preferably any one or mixture of at least two selected from the group of crystalline silica, fused-silica, spherical silica, hollow silica, glass powder, aluminum nitride, boron nitride, silicon carbide, aluminum hydroxide, titanium oxide, strontium titanate, barium titanate, alumina, barium sulfate, talc powder, calcium silicate, calcium carbonate or mica. The mixture is such as the mixture of crystalline silica and fused-silica, the mixture of spherical silica and hollow silica, the mixture of glass powder and aluminum nitride, the mixture of boron nitride and silicon carbide, the mixture of aluminum hydroxide, titanium oxide, the mixture of strontium titanate, barium titanate and alumina, the mixture of barium sulfate, talc powder, calcium silicate, calcium carbonate and mica.

The organic filler is any one or mixture of at least two selected from the group of polytetrafluoroethylene powder, polyphenylene sulfide, Organophosphorus compounds or polyether sulfone powder. The mixture is such as the mixture of polytetrafluoroethylene powder and polyphenylene sulfide, and the mixture of organophosphorus compounds and polyether sulfone powder.

In addition, there is no special limitation for the shape and particle diameter of the filler. Preferably, the median particle diameter of the filler is 0.01-50 μm, such as 1 μm, 3 μm, 7 μm, 12 μm, 25 μm, 28 μm, 32 μm, 37 μm, 43 μm, 47 μm, 49 μm, preferably 0.01-20 μm, and more preferably 0.1-10 μm. The inorganic filler with the particle size within this range is more easily dispersed in the resin liquid.

Furthermore, there is no special limitation for the addition amount of component (E) filler. Based on the calculation of total weight of the component (A), component (B) and component (C) as 100 weight parts, the addition amount of the component (E) filler is 5-1000 weight parts such as 10 weight parts, 80 weight parts, 120 weight parts, 230 weight parts, 350 weight parts, 450 weight parts, 520 weight parts, 680 weight parts, 740 weight parts, 860 weight parts, 970 weight parts, preferably, 5-300 weight parts, more preferably 5-200 weight parts, and particularly preferably 15-150 weight parts.

If necessary, the thermosetting resin composition of the present invention further comprises component (F) curing promotor. There is no special limitation for the curing promotor but catalyzing the curing the reaction of cyanate ester, cyanate ester and epoxy resin. The curing promotor is selected from organic metal compounds, such as one or mixture of at least two selected from the group of copper, zinc, cobalt, nickel, iron, imidazole compounds and their derivatives or tertiary amine; the illustrative component (F) curing promotor is any one or mixture of at least two selected from the group of 2-methylimidazoline, 2-Phenylimidazole, 2-ethyl-4-methylimidazole, tributylamine, triphenyl phosphine, boron trifluoride complex, octanoic acid metal salt, acetylacetone metal salt, metal naphthenate, salicylic acid metal salt and metallic stearates; the mixture are such as the mixture of metallic stearates and salicylic acid metal salt, the mixture of metal naphthenate and acetylacetone metal salt, the mixture of octanoic acid metal salt and boron trifluoride complex, the mixture of triphenyl phosphine and tributylamine, the mixture of 2-ethyl-4-methylimidazole and 2-phenylimidazole, the mixture of octanoic acid metal salt and Ttributylamine, the mixture of 2-ethyl-4-methylimidazole, the mixture of tributylamine and 2-phenylimidazole, wherein the metal is any one or mixture of at least two selected from the group of zinc, copper, iron, tin, cobalt and aluminum.

Based on the calculation of total weight of the component (A), component (B) and component (C) as 100 weight parts, the addition amount of the component (F) curing promotor is 0.01-1.0 weight parts, such as 0.02 weight parts, 0.1 weight parts, 0.2 weight parts; 0.3 weight parts, 0.5 weight parts, 0.7 weight parts, 0.9 weight parts, 0.95 weight parts, preferably 0.05-0.85 weight parts and more preferably 0.1-0.8 weight parts.

A thermosetting resin composition, wherein the resin composition comprises (A) epoxy resin with main chain containing naphthol structure and (B) cyanate ester compounds or/and isocyanate ester prepolymer: 70-95 weight parts, (C) polyphosphonate ester or/and phosphonate-carbonate copolymers: 5-30 weight parts; based on the calculation of usage amount of (A) epoxy resin with main chain containing naphthol structure as 100 weight parts, the addition amount of (B) cyanate ester compounds or/and isocyanate ester prepolymer is 20-100 weight parts; (D) the active ester curing agent: usage amount of the active ester curing agent is based on the ratio of epoxy equivalent and active ester equivalent and the equivalence ratio is 0.25-1.0, preferably equivalent ratio is 0.3-0.95, most preferably equivalence ratio is 0.4-0.7; (E) filler: based on the calculation of total weight of the component (A), component (B) and component (C) as 100 weight parts, the addition amount of the filler is 5-1000 weight parts; (F) curing promoter: based on the calculation of total weight of the component (A), component (B) and component (C) as 100 weight parts, the addition amount of the component (F) curing promoter is 0.01-1.0 weight parts.

As used herein, the term “comprise” in the present invention means “to also include the other components besides the components mentioned already. Those “other components” give different characteristics to the resin composition. In addition, the term “comprises” in the present invention also can be replaced by closed type “is” or “consisting of”.

For example, the thermosetting resin composition of the present invention can be added with formulated thermosetting resin. Specific examples of the present invention include polyphenylene ether resin, phenolic resin, polyurethane resin, melamine resin etc. Curing agent or cured agent promotor of the thermosetting resin composition can also be added.

In addition, the thermosetting resin composition can also comprise various additives. Specific examples of the present invention include antioxidant, heat stabilizer, antistatic agent, ultraviolet absorbent, pigments, colorants, lubricant etc. The thermosetting resin and various additives can be used alone, also can be used in mixture of two or more.

The preparation methods of the resin composition of the present invention can be achieved according to the method disclosed in the prior art by formulating, stirring and mixing component (A), component (B), component (C), curing promotor, filler, various thermosetting resin and various additives.

The resin glue can be obtained by dissolving or dispersing the thermosetting resin composition mentioned above in the solvent.

There is no special limitation for the solvent of the present invention, Specific examples include alcohol solvent of Methanol, ethanol, butanol etc., ether solvent of Ethyl cellosolve, Butyl cellosolve, glycol monomethyl ether, carbitol, Butyl carbitol etc., ketone solvent of acetone, butanone, methyl ethyl ketone, methyl isobutyl ketone, cyclohexanone etc., Aromatic hydrocarbon solvent of Toluene, xylene, 1,3,5-trimethylbenzene etc., ester solvent of Ethoxy ethyl acetate, ethyl acetate etc., nitrogen containing solvent of N, N-dimethyl formamide, N, N-dimethyl acetamide, N-methyl-2-pyrrolidone etc. The solvents mentioned above can be used alone or be used in mixture of two or more, preferably, the mixture of aromatic hydrocarbon solvent, such as Toluene, xylene, 1,3,5-trimethylbenzene etc., and ketone solvent such as acetone, butanone, methyl ethyl ketone, methyl isobutyl ketone, cyclohexanone etc. The usage amount of the solvent can be chosen by those skilled in the art according to their own experiences, to obtain the viscosity of the resin glue suitable for use.

Emulsifier can be added during the dissolving process or dispersing process of the resin composition mentioned above. The powder filler can be dispersed uniformly in glue solution by dispersion of emulsifier.

The second object of the present invention is to provide a prepreg, which comprises the enhancement material and the thermosetting resin composition mentioned above, which adhere to the enhancement material after impregnation and then drying. There is no special limitation for the enhancement material, which can be organic fiber, inorganic fiber woven cloth or non-woven fabrics, wherein, the organic fiber is preferably Kevlar nonwoven, the inorganic fiber woven cloth is preferably E-glass fiber, D-glass fiber, S-glass fiber, T-glass fiber, NE-glass fiber and quartz cloth. There is no special limitation for the thickness of the enhancement material. In respect of laminate's application, and concerning good dimensional stability, the thickness of the woven cloth or non-woven fabric optimization is preferably 0.01-0.2 mm, and preferably processed through open fiber processing and surface treatment with silane coupling agent. In order to provide good water resistance and heat resistance, the silane coupling agent is preferably any one or mixture of at least two selected from a group consisting of epoxy silane coupling agent, amino silane coupling agent or any vinyl silane coupling agent. The prepreg is obtained by impregnating the prepreg made from the thermosetting resin composition, baking for 2-10 minutes at 100-200° C. and drying.

The third object of the present invention is to provide a laminate, which comprises at least one prepreg mentioned above. One or a few pieces of prepreg mentioned above are stacked together in certain order, one side or both sides of the stacked prepreg were covered with copper foil and it is cured in the hot press machine to prepare copper clad laminate. Or one or a few pieces of prepreg mentioned above are stacked together in certain order, one side or both sides of the stacked prepreg were covered with release film and it is cured in the hot press machine to prepare insulation board or single clad board. The curing temperature is 150-250° C. and the curing pressure is 25-60 kg/cm². The prepreg and the laminate of the present invention have excellent dielectric properties and wet-heat resistance, and they also have high glass transition temperature, low water absorption rate, and meanwhile achieve the halogen-free flame resistance of UL 94 V-0 level.

The fourth object of the present invention is to provide a high-frequency circuit board, which comprises at least one prepreg mentioned above and the copper foil cladded on both sides of the stacked prepregs.

Compared with prior art, the present invention has the following beneficial effects: \hat{1} The thermosetting resin provided by the present invention has a low dielectric constant, dielectric loss tangent; \hat{2} the present invention further adopts the polyphosphonate ester and/or phosphonate-carbonate copolymer as flame retardant, thereby halogen-free flame resistance is achieve and the flame resistance of the cured products reach UL 94 V-0 level, without sacrificing the heat resistance, low water absorption and excellent dielectric property of the original cured product, \hat{3} due to the excellent char formation property of the naphthalene structure, the epoxy resins with main chain containing naphthalene structure of the present invention can take a synergistic flame resistance effect with the flame retardant of the present invention and reduce the usage amount of fire retardant; \hat{4} the prepreg and the copper-clad laminate of the present invention prepared with the thermosetting resin composition mentioned above has excellent dielectric properties, wet-heat resistance, flame resistance of UL 94 V-0 level and good processing characteristics.

### DETAILED DESCRIPTION

To better illustrate the present invention and understand technical solution of the present invention, the typical but non-limiting embodiments of the present invention are as follows:

Addressing the prepared copper clad laminate mentioned above, dielectric constant, dielectric loss factor, glass transition temperature and wet-heat resistance are all measured, and further described referring to the following embodiments.

### Embodiment 1

A container is taken, added with bisphenol A type cyanate ester resin BA230S (LONZA Company, Cyano equivalent is 139 g/eq) of 49 weight parts, and naphthol novolac epoxy resin NC-7000L (Nippon Kayaku Co., Ltd., EEW is 232 g/eq) of 21 weight parts, then added with phosphonate carbonate copolymer FRX 95 (FRX Polymers Company, the phosphorus content is 10.6%) of 30 weight parts and stirred uniformly. Then it is added with curing promoter Zinc caprylate of 0.035 weight parts and solvent butanone and stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded on both sides of the stacked prepregs, and they are cured in a hot press machine to obtain a copper clad laminate. The cured temperature is 150-250° C., cured press is 25-60 kg/cm² and cured time is 90-120 min.

### Embodiment 2

A container is taken, added with bisphenol A type cyanate ester resin BA230S (LONZA Company, Cyano equivalent is 139 g/eq) of 50 weight parts, and naphthol novolac epoxy resin NC-7300L (Nippon Kayaku Co., Ltd., EEW is 214 g/eq) of 45 weight parts, then added with phosphonate polymers HM1100 (FRX Polymers, phosphorus content is 10.8%) of 30 weight parts and stirred uniformly. Then it is added with curing promoter Zinc caprylate of 0.035 weight parts and solvent butanone and stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded on both sides of the stacked prepregs, and they are cured in a hot press machine to obtain a copper clad laminate. The cured temperature is 150-250° C., cured press is 25-60 kg/cm² and cured time is 90-120 min.

### Embodiment 3

A container is taken, added with novolac cyanate ester resin PT-30 (LONZA, cyano equivalent is 139 g/eq) of 30 weight parts, and naphthol novolac epoxy resin NC-7300L (Nippon Kayaku Co., Ltd., EEW is 214 g/eq) of 50 weight parts, then added with phosphonate oligomer OL5000 (FRX Polymers, the phosphorus content is 10.8%) of 20 weight parts and stirred uniformly. Then it is added with curing promoter Zinc caprylate of 0.035 weight parts and solvent butanone and stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded on both sides of the stacked prepregs, and they are cured in a hot press machine to obtain a copper clad laminate. The cured temperature is 150-250° C., cured press is 25-60 kg/cm² and cured time is 90-120 min.

### Embodiment 4

A container is taken, added with bisphenol A cyanate ester resin BA230S (LONZA, cyano equivalent is 139 g/eq) of 17 weight parts, and naphthol novolac epoxy resin NC-7000L (Nippon Kayaku Co., Ltd., EEW is 232 g/eq) of 38.5 weight parts, then added with active ester curing agent HPC-8000-65T of 21.5 weight parts and then phosphonate-carbonate copolymer FRX OL3001 (FRX Polymers, the phosphorus content is 10.0%) of 23 weight parts and stirred uniformly. Then it is added with curing promoter Zinc caprylate of 0.035 weight parts and solvent butanone and stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded on both sides of the stacked prepregs, and they are cured in a hot press machine to obtain a copper clad laminate. The cured temperature is 150-250° C., cured press is 25-60 kg/cm² and cured time is 90-120 min.

### Embodiment 5

A container is taken, added with bisphenol A cyanate ester resin BA230S (LONZA, cyano equivalent is 139 g/eq) of 17 weight parts, naphthol novolac epoxy resin NC-7000L (Nippon Kayaku Co., Ltd., EEW is 232 g/eq) of 38.5 weight parts, active ester curing agent HPC-8000-65T (Japan DIC, active ester equivalent is 223 g/eq) of 21.5 weight parts, phosphonate-carbonate copolymer FRX C06000 (FRX Polymers, the phosphorus content is 6.5%) of 23 weight parts and spherical silica powder SO—C2 (Japan ADMATECHS, the median particle size: 0.5 um) of 50 weight parts, and stirred uniformly. Then it is added with curing promoter Zinc caprylate of 0.035 weight parts and solvent butanone and stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded on both sides of the stacked prepregs, and they are cured in a hot press machine to obtain a copper clad laminate. The cured temperature is 150-250° C., cured press is 25-60 kg/cm² and cured time is 90-120 min.

### Comparative Example 1

A container is taken, added with novolac cyanate ester resin PT-30 (LONZA Company) of 30 weight parts and naphthol novolac type epoxy resin NC-7300L (Japan DIC Company, EEW is 214 g/eq) of 50 weight parts, then added with flame retardant phosphate PX-200 (Daihachi Chemical Industry, phosphorus content is 9%) of 20 weight parts and stirred uniformly. Then it is added with curing promoter Zinc caprylate of 0.035 weight parts and solvent butanone and stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded on both sides of the stacked prepregs, and they are cured in a hot press machine to obtain a copper clad laminate. The cured temperature is 150-250° C., cured press is 25-60 kg/cm² and cured time is 90-120 min.

### Comparative Example 2

A container is taken, added with bisphenol A cyanate ester resin BA230S (LONZA, cyano equivalent is 139 g/eq) of 17 weight parts, O-Cresol type phenolic epoxy resin N690 (Nippon Kayaku Co., Ltd., EEW is 215 g/eq) of 38.5 weight parts, the active ester curing agent HPC-8000-65T (Japan DIC, active ester equivalent is 223 g/eq) of 21.5 weight parts, phosphonate-carbonate copolymer FRX C06000 (FRX Polymers, phosphorus content is 6.5%) of 23 weight parts and spherical silica powder SO—C2 (Japan ADMATECHS, the median particle size: 0.5 um) of 50 weight parts and stirred uniformly. Then it is added with curing promoter Zinc caprylate of 0.035 weight parts and solvent butanone and stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded on both sides of the stacked prepregs, and they are cured in a hot press machine to obtain a copper clad laminate. The cured temperature is 150-250° C., cured press is 25-60 kg/cm² and cured time is 90-120 min.

### Comparative Example 3

A container is taken, added with naphthol novolac epoxy resin NC-7300L (Nippon Kayaku Co., Ltd., EEW is 214 g/eq) of 75 weight parts, then polyphosphonate ester polymer HM1100 (FRX Polymers, phosphorus content is 10.8%) of 25 weight parts and solvent butanone, and stirred uniformly into glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded on both sides of the stacked prepregs, and they are cured in a hot press machine to obtain a copper clad laminate. The cured temperature is 150-250° C., cured press is 25-60 kg/cm² and cured time is 90-120 min. It is found that the system cannot be cured thereby the copper clad laminate materials cannot be prepared.

TABLE 1
Physical Property Data of Each Embodiment and Comparative Example

| Performance | | | | | | Comparative | Comparative |
|---|---|---|---|---|---|---|---|
| Index | Embodiment 1 | Embodiment 2 | Embodiment 3 | Embodiment 4 | Embodiment 5 | example 1 | example 2 |
| Tg(DMA)/° C. | 225 | 220 | 275 | 220 | 215 | 210 | 220 |
| Dk(5G) | 3.8 | 3.85 | 3.85 | 3.7 | 3.85 | 3.7 | 3.8 |
| Df(5G) | 0.0075 | 0.008 | 0.0085 | 0.006 | 0.0055 | 0.009 | 0.0095 |
| Water | 0.10 | 0.11 | 0.15 | 0.10 | 0.085 | 0.20 | 0.12 |
| Absorption % | | | | | | | |
| Wet-heat | 3/3 | 3/3 | 3/3 | 3/3 | 3/3 | 0/3 | 2/3 |
| Resistance | | | | | | | |
| Flame | V-0 | V-0 | V-0 | V-0 | V-0 | V-0 | V-1 |
| Resistance | | | | | | | |

The testing methods of performance above are as follows:

(1) glass transition temperature (Tg): measuring with DMA assay. Taking measurement with the DMA assay specified in IPC-TM-650 2.4.24;

(2) dielectric constant and dielectric loss factor: taking measurement with SPDR method;

(3) wet-heat resistance evaluation: evaluating the substrate lamina after the copper foil on the surface of copper-clad laminate was etched; treating the substrate lamina in a pressure cooker at 120° C., 105 KPa for 4 h; then impregnating the substrate lamina in a tin furnace at 288° C.; recording the corresponding time once the substrate lamina is delaminated; ending the evaluation if no bubble or delamination occurred after the substrate lamina was in a tin furnace for 5 min;

(4) flame resistance: measuring with UL94 standard method.

### Physical Properties Analysis

It is known by the physical property data of table 1, in Comparative Example 1, the prior phosphate is used as a flame retardant. In comparison with embodiment 1˜5, its plasticizer is great, the resulted glass transition temperature of the curing system is largely reduced, at the meantime water absorption rate is high and the heat resistance is poor, thus unable to meet the requirements of heat resistance of lead free technology. In comparative example 2, the prior phenolic resin is used. Due to the low charring formation property of the structure, it cannot meet the constituency requirements of flame retardant. The wet-heat resistance is poor, water absorption rate is greater and in the meantime the dielectric loss tangent value is increased.

As stated above, compared with the common copper-clad laminate, the copper-clad laminate of the present invention achieves halogen-free flame resistance, and at the same time has excellent dielectric properties, higher glass transition temperature, and good wet-heat resistance, thus it is suitable for the application field of lead-free high speed communication.

The above are merely preferred embodiments of the present invention. Those skilled in the art can make numerous variations and changes according to the technical solution and spirit of the present invention, which all fall in the protection scope of the claims of the present invention.

The applicant stated that the present invention employ the embodiments above to describe the detailed components of the present invention, but the present invention is not limited to the detailed components above, i.e. it does not mean that the present invention must rely on the detailed components above to be implemented. Persons skilled in the art should understand, any improvement of the present invention, the equivalent replacement to the raw materials of the present invention product, adding auxiliary ingredients, specific mode selection, etc. all fall within the protection scope and disclosure scope of the present invention.

1. A thermosetting resin composition comprising of:
(A) epoxy resin with main chain containing naphthol structure;
(B) cyanate ester compounds or/and cyanate prepolymer;
(C) polyphosphonate ester or/and phosphonate-carbonate copolymer.

2. The thermosetting resin composition according to claim 1, wherein the structural formula of the polyphosphonate ester is as follows: 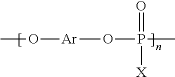
wherein Ar is an aryl, —O—Ar—O— is selected from the group consisting of resorcinol active group, hydroquinone active group, bisphenol A active group, bisphenol F active group, 4,4′-bisphenol, phenolphthalein active group, 4,4′-thiodiphenol active group, 4,4′-sulfonyl diphenol active group and 3,3,5-trimethylcyclohexyl diphenol active group; X is substituted or unsubstituted C1-C20 straight-chain alkyl, substituted or unsubstituted C1-C20 branched-chain alkyl, substituted or unsubstituted C2-C20 straight-chain alkenyl, substituted or unsubstituted C2-C20 branched-chain alkenyl, substituted or unsubstituted C2-C20 straight-chain alkylene, substituted or unsubstituted C2-C20 branched-chain alkylene, substituted or unsubstituted C5-C20 cycloalkyl, or substituted or unsubstituted C6-C20 branched-chain aryl; n is any integer from 1 to 75.

3. The thermosetting resin composition according to claim 1, wherein, the structural formula of the phosphonate-carbonate copolymer is as follows: 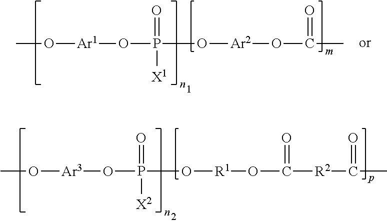
wherein, Ar¹, Ar² and Ar³ are each independently selected from aryl and —O—Ar³—O— is selected from the group consisting of resorcinol active group, hydroquinone active group, bisphenol A active group, bisphenol F active group, 4,4′-bisphenol, phenolphthalein activity group, 4,4′-thiodiphenol active groups, 4,4′-sulfonyl diphenol active group and 3,3,5-trimethylcyclohexyl diphenol active group; X¹ and X² are each independently substituted or unsubstituted C1-C20 straight-chain alkyl, substituted or unsubstituted C1-C20 branched-chain alkyl, substituted or unsubstituted C2-C20 straight-chain alkenyl, substituted or unsubstituted C2-C20 branched-chain alkenyl, substituted or unsubstituted C2-C20 straight-chain alkylene, substituted or unsubstituted C2-C20 branched-chain alkylene, substituted or unsubstituted C5-C20 cycloalky, or substituted or unsubstituted C6-C20 branched-chain aryl; m is any integer from 1 to 100, n₁ and n₂ are each independently any integer from 1 to 75, and P is any integer from 2 to 50; R¹, R² are each independently selected from the group consisting of substituted or unsubstituted aliphatic or aromatic hydrocarbon group.

4. The thermosetting resin composition according to claim 1, wherein, the structural formula of the epoxy resin with main chain containing naphthol structure is as follows: 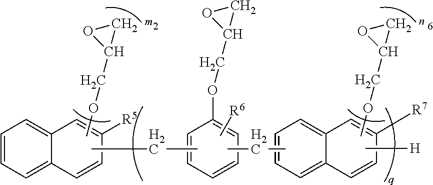
wherein, m₂ and n₆ are each independently selected from the group consisting of 0, 1 or 2, q is any integer from 1 to 10, and m₂+n₆+q≧2, R⁵, R⁶, R⁷ are each independently any one selected from the group consisting of H, substituted or unsubstituted C1-C5 straight-chain alkyl, substituted or unsubstituted C1-C5 branched-chain alkyl or alkoxy.

5. The thermosetting resin composition according to claim 1, wherein, the polyphosphonate ester or/and phosphonate-carbonate copolymer is any one or mixture of at least two selected from the group of 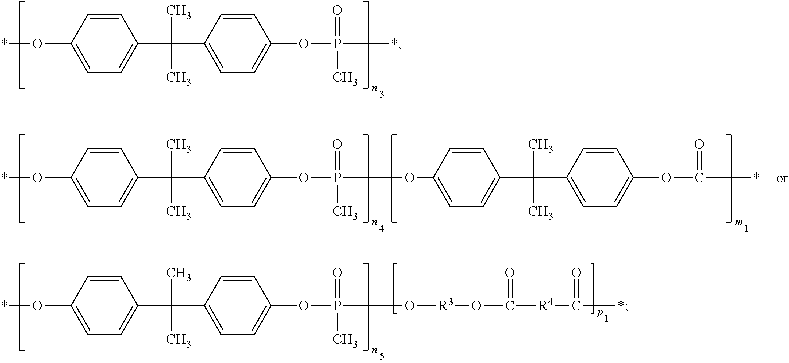
wherein, R³ and R⁴ are each independently selected from substituted or unsubstituted aliphatic or aromatic hydrocarbon groups; m₁ is any integer from 1 to 100; n₃, n₄ and n₅ are each independently any integer from 1 to 75; p₁ is any integer from 2 to 50.

6. The thermosetting resin composition according to claim 1, wherein the weight-average molecular weight of the polyphosphonate ester or phosphonate-carbonate copolymer is 1000-60000.

7. The thermosetting resin composition according to claim 6, wherein the cyanate ester compound has the following structure: 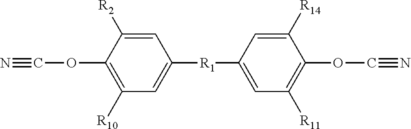
wherein, R₁ is selected from 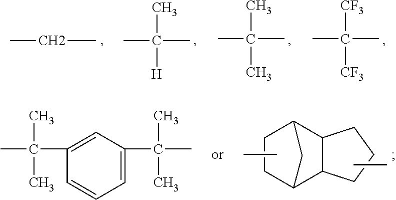
R₂, R₁₄, R₁₀, R₁₁ are each independently selected from hydrogen atom, substituted or unsubstituted C1-C4 straight-chain alkyl and substituted or unsubstituted C1-C4 branched-chain alkyl.

8. The thermosetting resin composition according to claim 6, wherein the isocyanate ester prepolymer has the following structure: 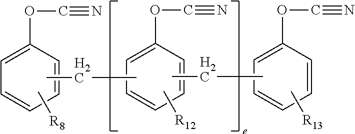
wherein, R₈, R₁₂, R₁₃ are each independently selected from hydrogen atoms, substituted or unsubstituted C1-C4 straight-chain alkyl or substituted or unsubstituted C1-C4 branched-chain alkyl, e is any integer from 1 to 7.

9. The thermosetting resin composition according to claim 6, wherein, the component (B) is any one or mixture of at least two selected from the group consisting of 2,2-bis(4-cyanatophenyl)propane, bis(4-cyanatophenyl)ethane, bis(3,5-dimethyl-4-cyanatophenyl)methane, 2,2-bis(4-cyanatophenyl)-1,1,1,3,3,31,1,1,3-hexafluoropropane, α,α′-bis(4-cyanatophenyl)-m-diisopropylbenzene, cyclopentadiene-type cyanate, phenol novolac cyanate ester, cresol novolac cyanate ester, 2,2-bis(4-cyanatophenyl)propane prepolymer, bis(4-cyanatophenyl)ethane prepolymer, bis(3,5-dimethy-4-cyanatophenyl)methane prepolymer, 2,2-bis(4-cyanatophenyl)-1,1,1,3,3,3-hexafluoropropane prepolymer, α,α′-bis(4-cyanatophenyl)-m-diisopropylbenzene prepolymer, cyclopentadiene-type cyanate prepolymer, phenol novolac cyanate ester prepolymer and cresol novolac cyanate ester prepolymer; and
the epoxy resin with main chain containing naphthol structure is one or mixture of at least two selected from the epoxy resins having the following structures: 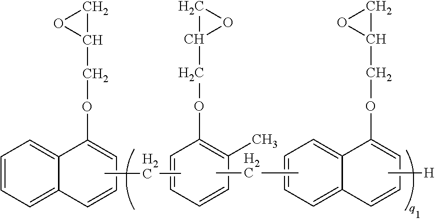
q₁ is any integer from 1 to 10;
or 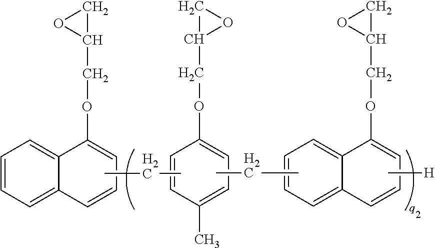
q₂ is any integer from 1 to 10;
or 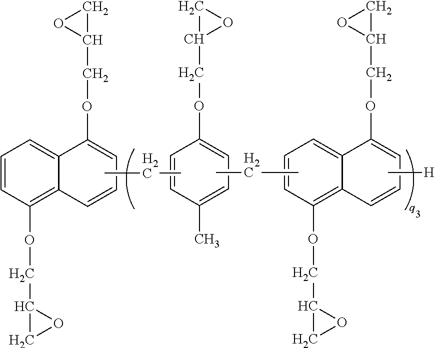
q₃ is any integer from 1 to 10;
or 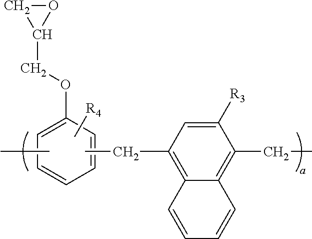
a is any integer from 2 to 10; R₃, R₄ are each independently selected from the group consisting of hydrogen atoms, substituted or unsubstituted C1-C5 straight-chain alkyl, and substituted or unsubstituted C1-C5 branched-chain alkyl or alkoxy.

10. The thermosetting resin composition according to claim 1, wherein the resin composition comprises the epoxy resin with main chain containing naphthol structure and cyanate ester compound or/and isocyanate ester prepolymer of 70-95 weight parts, and polyphosphonate ester or/and phosphonate-carbonate copolymer of 5-30 weight parts;
based on the epoxy resin with main chain containing naphthol structure of 100 weight parts, the addition amount of the cyanate ester compound or/and isocyanate ester prepolymer is 20-100 weight parts.
the thermosetting resin composition further comprise (D) active ester curing agent;
the active ester curing agent is prepared by reaction of the phenolic compounds with structural formula of 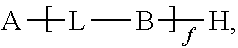
aromatic dicarboxylic acid or acid halides and monohydroxyl compounds, wherein, A, B are each independently a phenolic group, L is an alicyclic group and f is any integer from 1 to 5;
the phenolic compounds with structural formula of 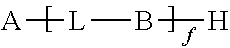
is any one or mixture of at least two selected from the phenolic compounds having the following structures: 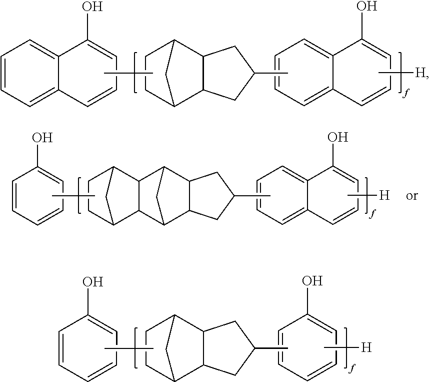
f is any integer from 1 to 5;
the aromatic dicarboxylic acid is any one or mixture of at least two selected from the aromatic carboxylic acids having the following structures: 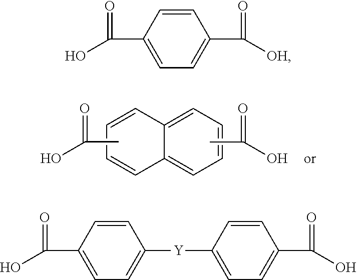
Y is selected from substituted or unsubstituted C1-C5 strain-chain alkylene or substituted or unsubstituted C1-C5 branched-chain alkylene; and
based on the aromatic dicarboxylic acid or acid halides of 1 mol, the usage amount of the phenolic compound with the structural formula of 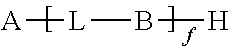
is 0.05-0.75 mol and the usage amount of monohydroxyl compounds is 0.25-0.95 mol.

11. The thermosetting resin composition according to claim 10, wherein the active ester curing agent has the following structural formula: 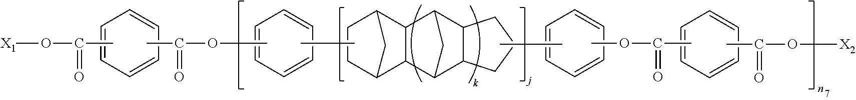
wherein, X₁ and X₂ are each independently selected from benzene ring or naphthalene ring, j is 0 or 1, k is 0 or 1, and n₇ represents the average repeat units of 0.25-2.5;
based on the ratio of the epoxy equivalent to the active ester equivalent, the equivalent ratio of the usage amount of the active ester curing agent is 0.25-1.0.

12. The thermosetting resin composition according to claim 11, wherein the thermosetting resin composition comprises (A) the epoxy resin with main chain containing naphthol structure and (B) cyanate ester compounds or/and isocyanate ester prepolymer of 70-95 weight parts; and (C) polyphosphonate ester or/and phosphonate-carbonate copolymer of 5-30 weight parts; and based on the usage amount of (A) the epoxy resin with main chain containing naphthol structure of 100 weight parts, the addition amount of (B) the cyanate ester compounds or/and isocyanate ester prepolymer is 20-100 weight parts.

13. The thermosetting resin composition according to claim 11, wherein the thermosetting resin composition comprises (A) the epoxy resin with main chain containing naphthol structure and (B) cyanate ester compounds or/and isocyanate ester prepolymer of 70-95 weight parts; and (C) polyphosphonate ester or/and phosphonate-carbonate copolymer of 5-30 weight parts; and based on the usage amount of (A) the epoxy resin with main chain containing naphthol structure of 100 weight parts, the addition amount of (B) the cyanate ester compounds or/and isocyanate ester prepolymer is 20-100 weight parts; based on the ratio of the epoxy equivalent to the active ester equivalent, the usage amount of the active ester curing agent is equivalence ratio of 0.25-1.0.

14. The thermosetting resin composition according to claim 11, wherein the thermosetting resin composition further comprise component (E) filler;
the filler is selected from organic or inorganic filler.

15. The thermosetting resin composition according to claim 14, wherein the inorganic filler is any one or mixture of at least two selected from the group consisting of nonmetal oxide, metal nitride, non-metal nitride, Inorganic hydrate, inorganic salt, Metal hydrate and inorganic phosphorus;
the organic filler is any one or mixture of at least two selected from the group of polytetrafluoroethylene powder, polyphenylene sulfide, organophosphorus compounds and polyether sulfone powder;
the median particle diameter of the filler is 0.01-50 μm;
based on the total weight of the component (A), component (B) and component (C) of 100 weight parts, the addition amount of the component (E) is 5-1000 weight parts.

16. The thermosetting resin composition according to claim 15, wherein the thermosetting resin composition further comprises component (F) curing promotor;
the curing promotor is any one or mixture of at least two selected from the group consisting of organic a metal compounds, an imidazole compound and derivatives thereof, a piperidine compound and a tertiary amine;
the curing promotor is any one or mixture of at least two selected from the group consisting of 2-methylimidazoline, 2-phenylimidazole, 2-ethyl-4-methylimidazole, tributylamine, triphenyl phosphine, boron trifluoride complex, octanoic acid metal salt, acetylacetone metal salt, metal naphthenate, salicylic acid metal salt and metallic stearates; wherein the metal is one or mixture of at least two selected from the group consisting of zinc, copper, iron, tin, cobalt and aluminum;
based on the total weight of the component (A), component (B) and component (C) of 100 weight parts, the addition amount of component (F) curing promotor is 0.01-1.0 weight parts.

17. The thermosetting resin composition according to claim 16, wherein the resin composition comprises (A) the epoxy resin with main chain containing naphthol structure and (B) cyanate ester compounds or/and isocyanate ester prepolymer of 70˜95 weight parts, and (C) polyphosphonate ester or/and phosphonat-carbonate copolymers of 5-30 weight parts;
based on the (A) the epoxy resin with main chain containing naphthol structure of 100 weight parts, the addition amount of the (B) cyanate ester compound or/and isocyanate ester prepolymer is 20-100 weight parts;
based on the ratio of the epoxy equivalent to the active ester equivalent, the equivalent ratio of the usage amount of the (D) active ester curing agent is 0.25-1.0;
based on the total weight of component (A), component (B) and component (C) of 100 weight parts, the addition amount of the (E) filler is 5-1000 weight parts; and
based on the calculation of total weight of component (A), component (B) and component (C) as 100 weight parts, the addition amount of the (F) curing promotor is 0.01-1 weight parts.

18. A prepreg, wherein the prepreg comprises enhancement material and the thermosetting resin composition according to claim 1 which adheres to the enhancement material by impregnation and drying.

19. A laminate, wherein the laminate comprises at least one prepreg according to claim 8.

20. A high-frequency circuit board, wherein the high-frequency circuit board comprises at least one prepreg according to claim 8 and the copper foil covered on both sides of the stacked prepregs.
